(19) United States
(12) Patent Application Publication
(10) Pub. No.: US 2026/0299170 A1
(43) Pub. Date: Oct. 1, 2026

(54) DISPLAY DEVICE

(71) Applicant: LG Display Co., Ltd., Seoul (KR)

(72) Inventors: Min Hyung KIM, Paju-si (KR); Ban Seok KANG, Paju-si (KR)

(73) Assignee: LG Display Co., Ltd., Seoul (KR)

(21) Appl. No.: 19/629,780

(22) Filed: Mar. 26, 2026

(30) Foreign Application Priority Data
Mar. 28, 2025 (KR) 10-2025-0040648

(51) Int. Cl. G02B 1/111; G02B 5/30; H10H 29/37; H10H 29/80; H10H 29/85; H10K 59/122; H10K 59/38; H10K 59/80

(52) U.S. Cl. CPC G02B 1/111; G02B 5/3025; H10H 29/37; H10H 29/8517; H10H 29/882; H10K 59/122; H10K 59/38; H10K 59/877

(57) ABSTRACT

A display device can include a display panel and an optical sheet disposed on the display panel. The optical sheet includes an adhesive layer disposed on the display panel, a base layer disposed on the adhesive layer, and an anti-glare layer disposed on the base layer. The anti-glare layer has a plurality of concave-convex portions, the adhesive layer includes scattering particles, and a haze of the anti-glare layer is lower than a total haze of the optical sheet.

### CROSS-REFERENCE TO RELATED APPLICATION

This application claims priority to and the benefit of Korean Patent Application No. 10-2025-0040648, filed in the Republic of Korea on Mar. 28, 2025, the disclosure of which is hereby expressly incorporated herein by reference in its entirety.

### BACKGROUND

### Field

An embodiment of the present disclosure relates to a display device with a suppressed sparkling phenomenon.

### Discussion of the Related Art

Various flat panel display devices such as a liquid crystal display device and an electroluminescence display device are well established. Unlike liquid crystal display devices, an electroluminescence display device can display an input image by emitting light by itself using light-emitting elements disposed in each of the pixels eliminating a need for a backlight. The light-emitting element of an electroluminescence display device can be categorized into an organic light-emitting element and an inorganic light-emitting element according to a material of an emission layer. In an active matrix organic light-emitting display device, a self-emissive organic light-emitting diode (hereinafter referred to as "OLED") is disposed in each pixel, and can provide several advantages such as fast response speed, high luminous efficiency, high luminance, and wide viewing angle. Further, since black grayscale levels can be expressed as perfect black, OLEDS offers improved contrast ratio and color reproduction.

Recently, market demand has expanded beyond television to a wider variety of applications, and demand for display devices with reduced image reflection is newly emerging.

In particular, in gaming monitors and specific TV models, application of surface treatment with high haze of approximately 10% or more is required to achieve high resolution while minimizing image reflection.

However, applying high haze surface treatment to high resolution products can introduce a sparkling phenomenon similar to stains is visible due to a lens effect caused by haze on the transmitted light.

### SUMMARY OF THE DISCLOSURE

An embodiment of the present disclosure provides a display device in which image reflection and sparkling phenomenon are suppressed.

An embodiment of the present disclosure provides a display device having excellent image quality with improved light extraction efficiency.

The problems of the present embodiments of the present disclosure are not limited to the problems mentioned above, and other problems not mentioned will be clearly understood by those skilled in the art from the description below.

A display device according to the embodiment of the present disclosure includes a display panel; and an optical sheet disposed on the display panel, wherein the optical sheet includes an adhesive layer disposed on the display panel; a base layer disposed on the adhesive layer; and an anti-glare layer disposed on the base layer, wherein the anti-glare layer has a plurality of concave-convex portions, the adhesive layer includes scattering particles, and a haze of the anti-glare layer is lower than a total haze of the optical sheet.

The anti-glare layer can include first particles, second particles, and a resin in which the first particles and the second particles are dispersed, and an average diameter of the first particles can be smaller than an average diameter of the second particles.

The display device can further include a polarizing layer disposed between the base layer and the anti-glare layer.

The display device can further include a first polarizing layer disposed between the base layer and the anti-glare layer, a second polarizing layer disposed between the first polarizing layer and the base layer, and an optical layer disposed between the first polarizing layer and the second polarizing layer, and the optical layer can include scattering particles.

A haze of the adhesive layer can be higher than a haze of the anti-glare layer.

A haze of the adhesive layer can be lower than a haze of the anti-glare layer.

The external haze of the anti-glare layer can be higher than the internal haze.

The external haze of the anti-glare layer can be lower than the internal haze.

The display device can further include a low refractive index layer disposed on the anti-glare layer, wherein the low refractive index layer can be formed to conform to the plurality of concave-convex portions.

The low refractive index layer can include low refractive index particles.

The low refractive index layer can include scattering particles.

Light reflected from the display panel can be primarily scattered by the scattering particles and secondarily scattered by the anti-glare layer.

The display panel can include a substrate; a circuit layer disposed on the substrate; a color filter layer disposed on the circuit layer; an insulating layer disposed on the color filter layer; a plurality of first electrodes disposed on the insulating layer; a pixel defining layer disposed between the plurality of first electrodes; an emission layer disposed on the plurality of first electrodes; and a second electrode disposed on the emission layer, wherein the color filter layer can include a first color filter, a second color filter, a third color filter, and a fourth color filter having different colors from each other.

The display panel can further include a scattering layer disposed between the color filter layer and the substrate.

The second color filter or the fourth color filter can include scattering particles, the second color filter can be a green color filter, and the fourth color filter can be a white color filter.

The second color filter or the fourth color filter can penetrate the insulating layer and contact a first electrode.

The display panel can include a substrate; a circuit layer disposed on the substrate; an emission layer disposed on the circuit layer; a light control layer disposed on the emission layer; and a color filter layer disposed on the light control layer, and the light control layer can include quantum dots and scattering particles.

According to an embodiment of the present disclosure, image reflection and sparkling phenomenon can be suppressed.

According to an embodiment of the present disclosure, light extraction efficiency can be improved, thereby implementing excellent image quality.

The effects of the present disclosure are not limited to the effects mentioned above, and other effects not mentioned will be clearly understood by those skilled in the art from the appended claims.

### BRIEF DESCRIPTION OF THE DRAWINGS

The above and other objects, features, and advantages of the present disclosure will become more apparent to those of ordinary skill in the art by describing example embodiments of the present disclosure thereof in detail with reference to the attached drawings, in which:

FIG. 1 is a conceptual diagram of a display device according to an embodiment of the present disclosure;

FIG. 2 is a conceptual diagram of a display device according to another embodiment of the present disclosure;

FIG. 3 is a plan view of a display device according to an embodiment of the present disclosure;

FIG. 4 is a view showing a state in which a sparkling phenomenon is visible in a display device;

FIG. 5 shows experimental results of image reflection and sparkling for a display device having an adhesive layer in which scattering particles are dispersed and a display device having an adhesive layer without scattering particles according to an embodiment of the present disclosure;

FIG. 6 is a first modified example of FIG. 2;

FIG. 7 is a second modified example of FIG. 2;

FIG. 8 is a conceptual diagram of a display device according to another embodiment of the present disclosure;

FIG. 9 is a first modified example of FIG. 8;

FIG. 10 is a second modified example of FIG. 8;

FIG. 11 is a third modified example of FIG. 8;

FIG. 12 is a fourth modified example of FIG. 8; and

FIG. 13 is a conceptual diagram of a display device according to another embodiment of the present disclosure.

### DETAILED DESCRIPTION OF THE EMBODIMENTS

Advantages and features of the present disclosure, and methods for achieving them will become clear by referring to the embodiments described in detail below together with the accompanying drawings. The present disclosure can be embodied in many different forms and should not be construed as being limited to the embodiments set forth herein, but rather the embodiments are provided so that the present disclosure will be thorough and complete, and will fully convey the scope of the disclosure to those skilled in the art to which the present disclosure belongs, and the present disclosure is only defined by the scope of the claims. Further, the term "can" encompasses all the meanings and coverages of the term "may" and vice versa.

Shapes, sizes, ratios, angles, numbers, etc. disclosed in the drawings for explaining embodiments of the present disclosure are examples, and thus the present disclosure is not limited to the matters shown in the drawings. Like reference numerals refer to substantially like elements throughout the present disclosure. In addition, in describing the present disclosure, when it is determined that a detailed description of related known technology can unnecessarily obscure the gist of the present disclosure, the detailed description thereof will be omitted.

When "comprises", "includes", "has", "consists of", etc. are used in the present disclosure, other parts can be added unless "only" is used. When a component is expressed in the singular, it can be interpreted as plural unless there is a specific explicit description.

In interpreting a component, even if there is no separate explicit description, it is interpreted to include an error range.

When a positional relationship and a mutual connection relationship between two components are described such as "on", "on an upper portion", "on a lower portion", "beside", "connect or couple", "crossing or intersecting", etc., one or more other components can be interposed between the components unless there is a mention such as "directly" or "immediately".

When a temporal sequential relationship is described with "after", "following", "next", or "before", etc., it need not be continuous on a time axis unless "directly" or "immediately" is used. The term “made of” for an element can fully encompass the meaning of being completely formed of the element, or simply including the element.

First, second, etc. can be used to distinguish components, but functions or structures of these components are not limited by ordinal numbers or component names in front of the components.

The following embodiments of the present disclosure can be combined or merged with each other partially or entirely, and various interlocking and driving are technically possible. Each of the embodiments can be independently implemented with respect to each other or can be implemented together in a related relationship.

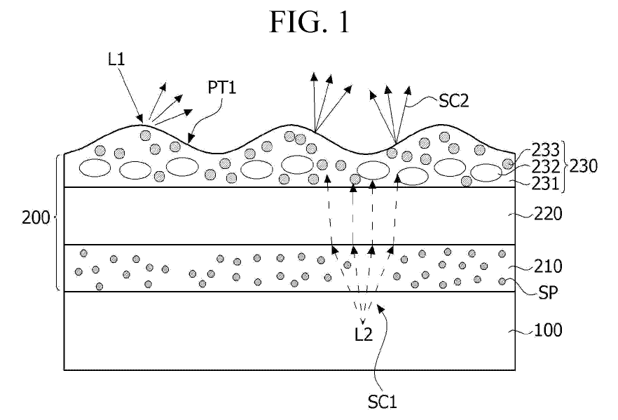

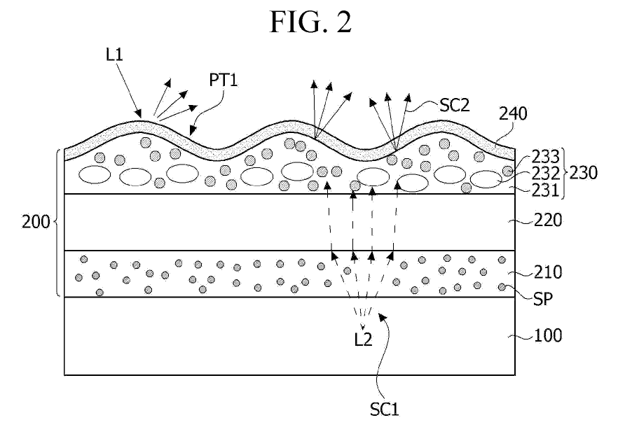

FIG. 1 is a conceptual diagram of a display device according to an embodiment of the present disclosure. FIG. 2 is a conceptual diagram of a display device according to another embodiment of the present disclosure. All components of each display device according to all embodiments of the present disclosure are operatively coupled and configured.

Referring to FIG. 1, a display device according to an embodiment of the present disclosure includes a display panel 100 and an optical sheet 200 disposed on the display panel 100. The display panel 100 can be one of various display panels such as a liquid crystal display panel, an electroluminescence display panel, an organic light emitting diode (OLED) display panel, and a micro LED display panel, and there is no limitation on types of display panel 100 that can be used.

The optical sheet 200 can include an adhesive layer 210 disposed on the display panel 100, a light-transmissive support 220 disposed on the adhesive layer 210, and an anti-glare layer 230 disposed on the light-transmissive support 220. The anti-glare layer 230 can be defined as a glare-proof layer, a reflection control layer, a reflection adjustment layer, an anti-reflection layer, or the like. In embodiments of the present disclosure, the anti-glare layer 230 can have a planar upper surface, or a non-planar upper surface.

Fine concave-convex portions PT1 can be formed on a surface of the anti-glare layer 230 as the non-planar upper surface. The plurality of concave-convex portions PT1 can include peaks and valleys. A height of the concave-convex portions PT1 can be random. The plurality of concave-convex portions PT1 can scatter incident light L1 to suppress projection of external light. Accordingly, the image reflection phenomenon, in which the incident light L1 is reflected and surrounding objects are reflected on a screen, can be suppressed. This image reflection can interfere with accurate color expression, thereby degrading image quality and increasing eye fatigue. With reference to FIG. 1, the concave-convex portions PT1 can be wave-like and have curvatures on surfaces, but the present embodiments are not limited thereto. For example, the concave-convex portions PT1 can be formed as periodic or random arrangement of pyramidal shapes having an apex and a polygonal base, a square wave having vertical sides, or arrangement of semicircle or hemispheres that are arranged in a regular matrix or randomly. In embodiments of the present disclosure, sizes of at least one of the convex portions and the concave portions of the concave-convex portions PT1 can be the same or different, and when different the sizes can be random or can be a mixture of one smaller size and one larger size structures, but the present embodiments are not limited thereto, and sizes of at least one of the convex portions and the concave portions of the concave-convex portions PT1 can be of several distinct sizes, but the present embodiments are not limited thereto.

The light-transmissive support 220 can be a layer serving as a base material for the optical sheet 200. The light-transmissive support 220 can be defined as a base layer, a substrate layer, or the like. The light-transmissive support 220 can be formed of a material having excellent transmittance of visible light. For example, the light-transmissive support 220 can use a transparent resin such as polyethylene, polyester, polyamide, polyimide, polyarylate, polycarbonate, triacetylcellulose, polyacrylate, polyvinyl alcohol, or polyvinyl chloride. A thickness of the light-transmissive support 220 can be 30 μm to 100 μm, but the present embodiments are not limited thereto.

A surface modification treatment can be performed on a surface of the light-transmissive support 220 to improve adhesion with another layer. Examples of the surface modification treatment can include alkali treatment, corona treatment, plasma treatment, sputter treatment, application of a surfactant or a silane coupling agent, Si deposition, and the like, but the present embodiments are not limited thereto.

The anti-glare layer 230 can include first particles 233, second particles 232, and a polymer resin 231. The first particles 233 can be inorganic particles and the second particles 232 can be organic particles, but the present embodiments are not limited thereto.

The polymer resin 231 can include a light-transmissive resin such as acrylate, but the present embodiments are not limited thereto. In addition to acrylate, various light-transmissive resins that are easy to disperse particles can be used, and types of resin that can be used are without limitation.

The first particles 233, which can be composed of inorganic particles, can form concave-convex portions by controlling the sedimentation or aggregation of the organic particles in the anti-glare layer 230. As the inorganic particles, metal particles such as silica or alumina can be used, but the present embodiments are not limited thereto.

The first particles 233 can be nanoparticles having an average particle diameter of 10 nm to 300 nm, but the present embodiments are not limited thereto.

The second particles 232, which can be composed of organic particles, can perform a function of diffusing and/or scattering external light. The second particles 232 can use resin particles made of a light-transmissive resin material such as acrylic resin, polystyrene resin, styrene-(meth)acrylic acid ester copolymer, polyethylene resin, epoxy resin, silicone resin, polyvinylidene fluoride, or polyfluoroethylene-based resin. However, the present embodiments are not limited thereto, In order to adjust a refractive index or dispersion of resin particles, two or more types of resin particles having different materials (refractive indexes) can be mixed.

The second particles 232 can be particles having an average particle diameter of 1.3 μm to 5.0 μm. The second particles 232 can have a larger average particle diameter (D50) than the first particles 233. However, the present embodiments are not limited thereto. For example, the first particles 233 and the second particles 232 can have the same size, or an average particle diameter of the first particles 233 can be larger than an average particle diameter of the second particles 232 but the present embodiments are not limited thereto.

With reference to FIG. 1, for example, both the first particles 233 and the second particles 232 can be all organic particles or all inorganic particles. Also, amounts or concentrations of the first particles 233 and the second particles 232 can vary. For example, an amount or concentration of the first particles 233 can be greater than an amount or concentration of the second particles, or vice -versa. Also, either the first particles 233 or the second particles 232 need not be used, so that the anti-glare layer 230 can include only one of the first particles 233 and the second particles 232. Also, additional particles can be included which can be the same or different material as those of the first particles 233 and the second particles 232, or the same or different sizes as those of the first particles 233 and the second particles 232 but the present embodiments are not limited thereto.

An average particle diameter (D50) means a typical average particle diameter (D50) known to those skilled in the art, and can mean a particle diameter of a particle corresponding to 50 volume % when particles are distributed in order from a minimum to a maximum based on volume.

Additionally, shapes of the first particles 233 and the second particles can be the same or similar, or can be different. For example, the first particles 233 can be round or spherical, and the second particles 232 can also be round or spherical, but the present embodiments are not limited thereto, and the first particles 233 can be round or spherical and the second particles 232 can be oval or elliptical or vice-versa. Also, one or both of the first particles 233 and the second particles 232 can have a polyhedron shape, or irregular shapes. When one or more of the first particles 233 and the second particles 232 have the oval or elliptical shapes, an orientation of the oval or elliptical shaped particle can be arranged in a predetermined direction, such as perpendicular to an optical axis of the anti-glare layer 230, but the present embodiments are not limited thereto, and the orientation of the oval or elliptical shaped particle can be arranged in between a direction parallel to the optical axis to a direction perpendicular to the optical axis of the anti-glare layer 230.

Additionally, the anti-glare layer 230 need not include both the first particles 233 and the second particles 232 in a single layer, but can be a plurality of layers or can include sub-layers that can include at least one of the first particles 233 and the second particles 232. In this regard, one anti-glare layer can include both the first particles 233 and the second particles 232 while another anti-glare layer can include one of the first particles 233 and the second particles 232, or one of the anti-glare layer can include the first particles 233 and the another anti-glare layer can include the second particles 232. Also, two or more anti-glare layers can include at least one of the first particles 233 and the second particles 232, and concentrations of the at least one of first particles 233 and the second particles 232 can be the same or different in the two or more anti-glare layers but the present embodiments are not limited thereto.

The adhesive layer 210 can attach the optical sheet 200 to the display panel 100. The adhesive layer 210 can be formed using a known adhesive. For example, the adhesive layer 210 can include a rubber-based adhesive, an acrylic-based adhesive, a silicone-based adhesive, a urethane-based adhesive, a polyvinyl alcohol-based adhesive, a polyvinyl pyrrolidone-based adhesive, a polyacrylamide-based adhesive, a cellulose-based adhesive, or a vinyl alkyl ether-based adhesive but the present embodiments are not limited thereto.

A thickness of the adhesive layer 210 can be approximately 5μm to approximately 30μm. If the thickness of the adhesive layer 210 is less than approximately 5μm , it can be not possible to sufficiently fill depressions, damage, or the like in the panel, resulting in visible defects; and if the thickness exceeds approximately 30μm, it can be difficult to achieve a thin profile.

The adhesive layer 210 can include scattering particles SP. The scattering particles SP can scatter reflected light L2 reflected by the display panel 100 among incident light. Known scattering particles can be applied to the scattering particles SP without limitation. For example, the scattering particles SP can be TiO2, Al2O3, SiO2, ZnO, ZrO2, BaTiO3, Ta2O5, Ti3O5, ITO, IZO, ATO, ZnO-Al, Nb2O3, SnO, and MgO, but the present embodiments are not limited thereto. In various embodiments of the present disclosure, a distribution of the scattering particles SP within the adhesive layer 210 can be random whereby the scattering particles SP are generally provided throughout a volume of the adhesive layer 210, but the present embodiments are not limited thereto. For example, the distribution of the scattering particles SP can be graded within the adhesive layer 210 so that there can be greater concentration of the scattering particles towards the light-transmissive support 220 or towards the display panel 100. When the distribution of the scattering particles SP is graded, then a change in concentrations between a sparse distribution of the scattering particles SP and a dense distribution of the scattering particles SP can be gradual such as linearly varying or exponentially varying, but the present embodiments are not limited thereto, and the change in concentrations between the sparse distribution of the scattering particles SP and a dense distribution of the scattering particles SP can occur in stepwise manner or abruptly. In other embodiments of the present disclosure, a plurality of adhesive layers 210 can be provided each with different or the same concentrations or distribution patterns of the scattering particles SP. The concentrations or distribution patterns of the scattering particles SP can be regular or matrix-like patterns or can be random patterns.

An average particle diameter of the scattering particles SP can be approximately 0.1 μm to approximately 4.0 μm . When the average particle diameter of the scattering particles SP is less than approximately 0.1 μm, the particles can be too small to effectively scatter light. As a result of an experiment, even when the average particle diameter of the scattering particles SP exceeded approximately 4.0 μm, an amount of scattering did not increase more than when the average particle diameter was approximately 2.0 μm. An average particle diameter of the scattering particles SP can be approximately 1.0 μm to approximately 3.0 μm according to an example embodiment.

According to an embodiment of the present disclosure, the reflected light L2 can undergo primary scattering (SC1) in the adhesive layer (210), which is positioned relatively close to the display panel 100. When the light-transmissive support 220 has a sufficient thickness, a sufficient optical distance can be formed between the adhesive layer 210 and the anti-glare layer 230. Accordingly, the primarily scattered light can be incident on the anti-glare layer 230 after being scattered as much as possible, thereby increasing the scattering effect. According to an embodiment of the present disclosure, since the amount of scattering of the reflected light L2 increases, a sparkling phenomenon that occurs due to relatively concentrated light can be reduced.

According to an embodiment of the present disclosure, the first particles 233 of the anti-glare layer 230 and the scattering particles SP of the adhesive layer 210 can include the same material. For example, the first particles 233 and the scattering particles SP can be composed of TiO2 or Al2O3. In addition, the first particles 233 of the anti-glare layer 230 can be a mixture of a plurality of inorganic particles, and one of the mixed inorganic particles can include the same material as the scattering particles SP of the adhesive layer 210 but the present embodiments are not limited thereto.

The anti-glare layer 230 can have a total haze of approximately 15% to approximately 70%. For example, the total haze of the anti-glare layer 230 can be approximately 25%, approximately 35%, or approximately 50%. An external haze of the anti-glare layer 230 can be greater than an internal haze. For example, when the total haze of the anti-glare layer 230 is approximately 25%, the external haze can be approximately 22.5% and the internal haze can be approximately 2.5%. When the external haze is greater than the internal haze, the image reflection phenomenon can be effectively reduced.

However, the external haze of the anti-glare layer 230 can be smaller than the internal haze. For example, when the total haze of the anti-glare layer 230 is approximately 35%, the external haze can be approximately 14.5% and the internal haze can be approximately 20.5%. When the internal haze is greater than the external haze, a sparkling phenomenon can be effectively suppressed. However, the present embodiments are not limited thereto.

The external haze can be defined as a haze generated by the concave-convex portions PT1 of the anti-glare layer 230. When the concave-convex portions PT1 increase or a height of the concave-convex portions PT1 increases, a scattering rate of incident light can increase and the external haze can increase.

The internal haze can be defined as a haze generated by a difference in refractive index between the polymer resin 231 and the second particles (e.g., organic particles 232). When the difference in refractive index between the polymer resin 231 and the second particles 232 increases, the internal haze can increase.

The total haze can be a haze obtained by adding the external haze and the internal haze.

A sparkling phenomenon can be defined as a phenomenon in which light reflected by the display panel 100 is condensed by a lens effect, thereby generating twinkling spots. The sparkling phenomenon can become more severe as resolution increases because an aperture area becomes smaller.

"Internal haze" can be a value evaluated in the same manner as the total haze after making the concave-convex portions on the surface of the anti-glare layer 230 flat using a transparent tape or the like. The total haze can be a value obtained by measuring the anti-glare layer 230 with a related haze meter. "External haze" can be a difference between the total haze and the internal haze of the anti-glare layer 230. However, the methods of measuring the internal haze and the external haze are not limited thereto, and various known measurement methods can be applied without limitation.

A haze of the adhesive layer 210 can be approximately 30% to approximately 50%. A haze of the adhesive layer 210 can be higher than a total haze of the anti-glare layer 230. However, the present embodiments are not limited thereto. A haze of the adhesive layer 210 can be lower than a total haze of the anti-glare layer 230. A haze of the adhesive layer 210 can be higher than an external haze or an internal haze of the anti-glare layer 230.

According to an embodiment of the present disclosure, a total haze of the optical sheet 200 can be determined by a sum of a haze of the anti-glare layer 230 and a haze of the adhesive layer 210. Accordingly, the total haze of the anti-glare layer 230 can be lower than a total haze of the optical sheet 200. In various embodiments of the present disclosure, a reference to a haze can refer to a percentage of transmitted light that deviates from an incident beam by more a predetermined degree, and can be determined using a haze meter or a spectrophotometer, for example. Various standards for measuring the haze can be used, including, but not limited to, ASTM D1003 standard or ISO 14782 standard.

Referring to FIG. 2, the optical sheet 200 can include an adhesive layer 210, a light-transmissive support 220, an anti-glare layer 230, and a low refractive index layer 240 laminated on a surface of the anti-glare layer 230. The optical sheet 200 can suppress projection and reflection of external light by using scattering of incident light L1 due to concave-convex portions PT1 on a surface and optical interference.

The low refractive index layer 240 has a refractive index lower than a refractive index of the anti-glare layer 230, and can suppress reflection by optical interference. The low refractive index layer 240 can be formed by applying a polymer resin to a surface of the anti-glare layer 230 and curing it. The low refractive index layer 240 can include low refractive index particles for refractive index control.

As the low refractive index particles, for example, particles such as LiF, MgF, 3NaF, or AlF, or silica particles having voids therein can be used. Silica particles having voids therein can be advantageous for lowering a refractive index of the low refractive index layer 240, because the portions of the voids can be adjusted to the refractive index of air. Specifically, porous silica particles or shell-structure silica particles can be used. However, the present embodiments are not limited thereto.

The low refractive index layer 240 can further include scattering particles. The scattering particles can be the same material as the scattering particles of the adhesive layer. According to an embodiment of the present disclosure, since scattering particles are also dispersed in the low refractive index layer 240, reflected light can be more effectively scattered and a sparkling phenomenon can be further suppressed.

In various embodiments of the present disclosure, one or more of the first particles 233, the second particles 232, and the scattering particles SP can be formed of hollow particles that have an internal space, which may be filled with gas, or one or more of the first particles 233, the second particles 232, and the scattering particles SP can be formed as a layered structure with a core and a shell, whereby the core and the shells can be of different materials, or can be the same material with different properties, such as optical properties.

Also, in various embodiments of the present disclosure, the thickness of the light-transmissive support 220 can be the same or greater than the thickness of the adhesive layer 210, but the present embodiments are not limited thereto. For example, a ratio of the thickness of the light-transmissive support 220 to the thickness of the adhesive layer 210 can be approximately 1.0 to approximately 20.0. For example, the ratio can be approximately 3.0. However, the present embodiments are not limited thereto.

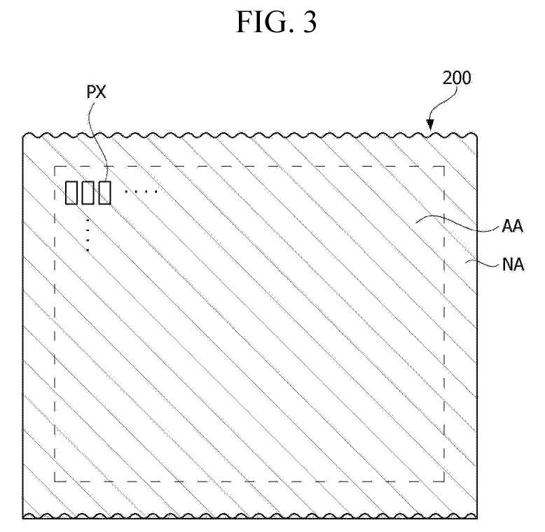

FIG. 3 is a plan view of a display device according to an embodiment of the present disclosure.

Referring to FIG. 3, the display panel 100 can include a display area AA that implements an image and a non-display area NA in which an image is not implemented. A plurality of pixels PX can be disposed in the display area AA. A gate driver or a wiring that applies a scan signal to the plurality of pixels PX can be disposed in the non-display area NA.

The optical sheet 200 according to an embodiment of the present disclosure can be disposed entirely on the display area AA and the non-display area NA. A plurality of display panels 100 can be manufactured on a mother substrate, an optical sheet can be entirely attached on the plurality of display panels, and then the structure can be cut into individual units of panels. Accordingly, the optical sheet 200 can be disposed entirely on the display panel 100. However, the present embodiments are not limited thereto. If necessary, an optical sheet can be attached after separating each display panel 100. In this case, the optical sheet 200 can be attached only to the display area AA of the display panel 100.

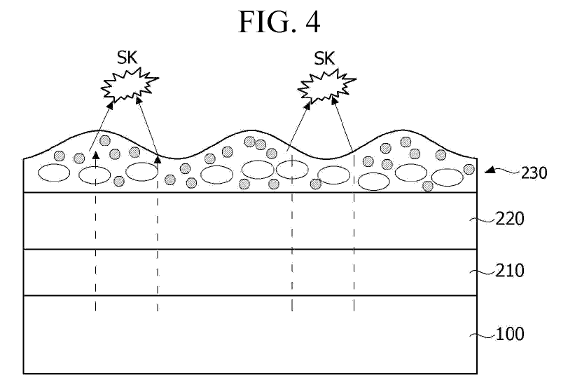

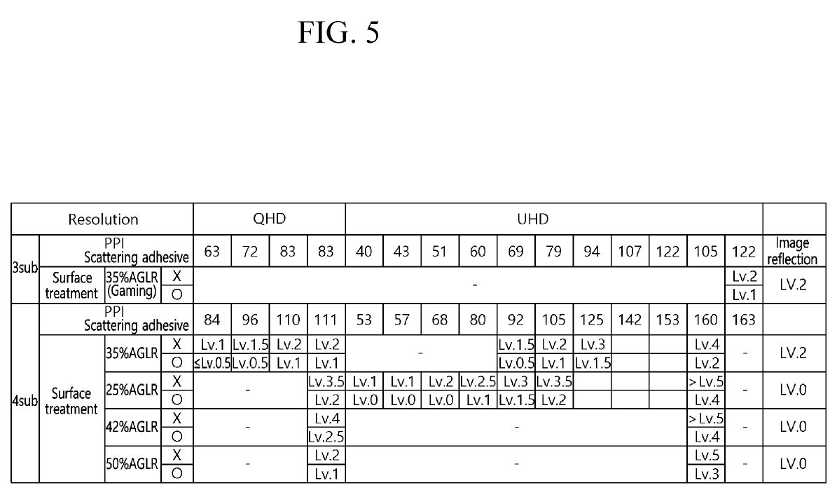

FIG. 4 is a view showing a state in which a sparkling phenomenon is visible in a display device. FIG. 5 is a result of an experiment on image reflection and sparkling of a display device having an adhesive layer in which scattering particles are dispersed and a display device having an adhesive layer without scattering particles according to an embodiment of the present disclosure.

Referring to FIG. 4, when the adhesive layer 210 does not have scattering particles, light reflected from the display panel 100 can reach the anti-glare layer 230 without scattering. Therefore, a sparkling phenomenon SK can occur as light is concentrated by a lens effect of the anti-glare layer 230 with high haze. This sparkling phenomenon SK can become stronger as the display panel has higher resolution.

Referring to FIG. 5, an experiment was conducted to determine whether image reflection and sparkling occurred in a display device (3sub) in which three RGB sub-pixels are disposed and a display device (4sub) in which four RGBW sub-pixels are disposed, depending on the presence or absence of scattering particles in the adhesive layer.

In the display device (3sub) in which three RGB sub-pixels are disposed, when the pixel density (PPI) was 122 and there were no scattering particles (SP) in the adhesive layer 210, a sparkling phenomenon was measured at level 2 (Lv.2). However, when there were scattering particles (SP) in the adhesive layer 210, it can be seen that the sparkling phenomenon decreased to level 1 (Lv.1). The sparkling level is a criterion classified based on the measured sparkling intensity. As the sparkling intensity increases, the level can increase. In this case, image reflection was the same at level 2 (Lv.2) regardless of the presence or absence of scattering particles. In the embodiment of the present disclosure, although the actual pixel density (PPI) was 163, it was displayed as 122 due to the smaller number of sub-pixels.

In a display device in which four RGBW sub-pixels are disposed, when the haze is 35%, it can be seen that as the resolution increases, a measurement level is lower when there are scattering particles (SP) in the adhesive layer 210 than when there are no scattering particles (SP) in the adhesive layer 210. For example, when the PPI is 92, the measurement level is 1.5 when there are no scattering particles (SP), whereas the measurement level is 0.5 when there are scattering particles (SP).

In addition, even when the PPI increases to 180, it can be seen that the measurement level is 2 or less when there are scattering particles (SP) in the adhesive layer 210. In contrast, when there are no scattering particles (SP) in the adhesive layer 210, it can be seen that the measurement level is 4, indicating that the sparkling phenomenon becomes very severe.

Even when the haze is 25%, 42%, or 50%, it can be seen that the measurement level is lower when there are scattering particles (SP) in the adhesive layer 210 than when there are no scattering particles (SP) in the adhesive layer 210. In this case, the image reflection was measured at level 0, and almost no image reflection was observed. However, the present embodiments are not limited thereto.

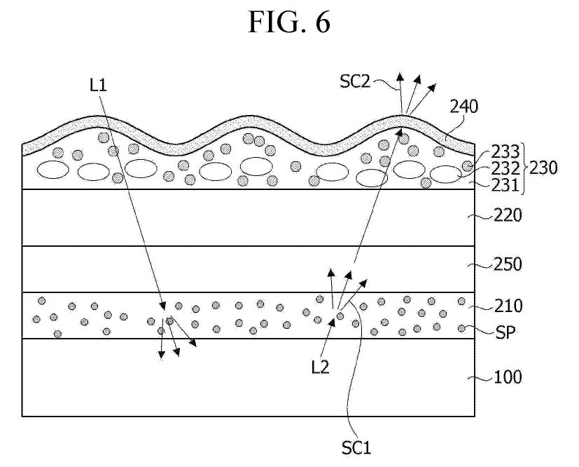

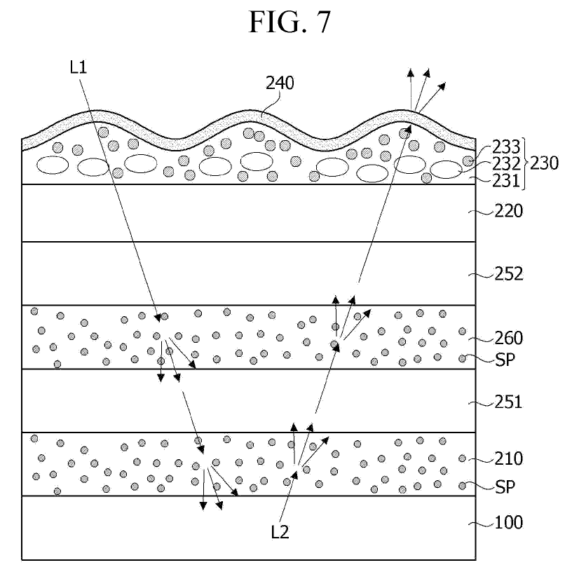

FIG. 6 is a first modified example of FIG. 2. FIG. 7 is a second modified example of FIG. 2.

Referring to FIG. 6, the optical sheet 200 can include a polarizing layer 250. The polarizing layer 250 can be disposed between the adhesive layer 210 and the light-transmissive support 220. The polarizing layer 250 can pass only light having a matching polarization direction among incident light.

Of the light incident from outside of the optical sheet 200, a portion is reflected by the anti-glare layer 230, but the reflected light is scattered, thereby minimizing image reflection.

Only some of the incident light L1 that has passed through the anti-glare layer 230 can pass through the polarizing layer 250. Light that has passed through the polarizing layer 250 can be scattered by the scattering particles SP of the adhesive layer 210.

Thereafter, reflected light L2 reflected by the display panel 100 can undergo primary scattering (SC1) while passing through the adhesive layer 210. Only some of the light that has passed through the adhesive layer 210 can pass through the polarizing layer 250. In addition, light that has passed through the polarizing layer 250 can undergo secondary scattering (SC2) while passing through the anti-glare layer 230.

According to an embodiment of the present disclosure, the reflected light L2 reflected by the display panel 100 is scattered twice by the adhesive layer 210 and the anti-glare layer 230, thereby reducing a sparkling phenomenon even when light is concentrated by a lens effect of the optical sheet 200. Accordingly, the optical sheet 200 according to an embodiment of the present disclosure can suppress both the image reflection phenomenon and a sparkling phenomenon.

Referring to FIG. 7, the polarizing layer can include a first polarizing layer 251 disposed between the adhesive layer 210 and the light-transmissive support 220, a second polarizing layer 252 disposed between the first polarizing layer 251 and the light-transmissive support 220, and an optical layer 260 disposed between the first polarizing layer 251 and the second polarizing layer 252.

The first polarizing layer 251 can be a circular polarizing layer, and the second polarizing layer 252 can be a linear polarizing layer.

Of the light L1 incident from outside the optical sheet 200, a portion is reflected by the anti-glare layer 230, and the reflected light is scattered so that image reflection can be minimized.

Only a portion of the light that has passed through the anti-glare layer 230 can pass through the second polarizing layer 252. The light that has passed through the second polarizing layer 252 can be scattered by the optical layer 260 and the adhesive layer 210.

Thereafter, reflected light L2 reflected by the display panel 100 can undergo primary scattering while passing through the adhesive layer 210, and can undergo secondary scattering while passing through the optical layer 260. Only a portion of the light that has passed through the optical layer 260 can pass through the second polarizing layer 252. The light that has passed through the second polarizing layer 252 can undergo tertiary scattering while passing through the anti-glare layer 230.

According to an embodiment of the present disclosure, the light reflected by the display panel 100 is scattered multiple times by the adhesive layer 210, the optical layer 260, and the anti-glare layer 230, thereby reducing a sparkling phenomenon even when light is concentrated by a lens effect of the optical sheet 200. Accordingly, the optical sheet 200 according to an embodiment of the present disclosure can suppress both the image reflection phenomenon and the sparkling phenomenon.

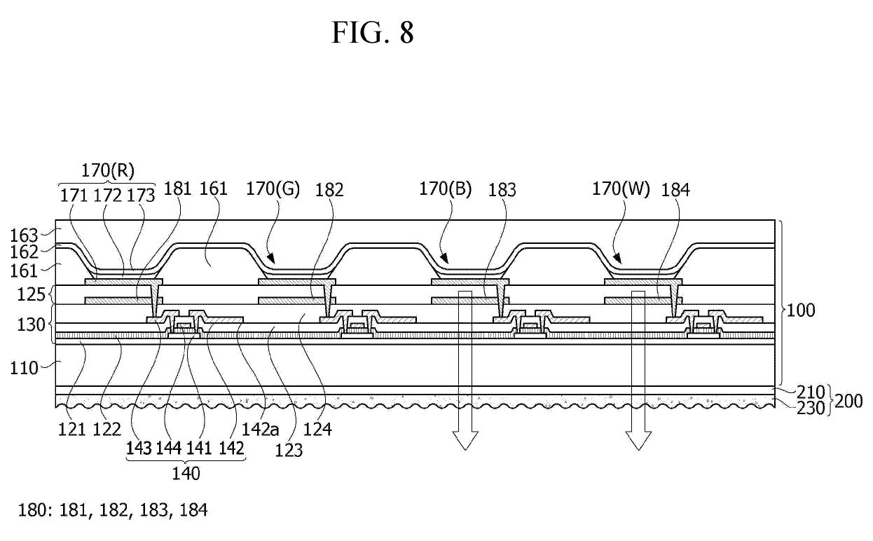

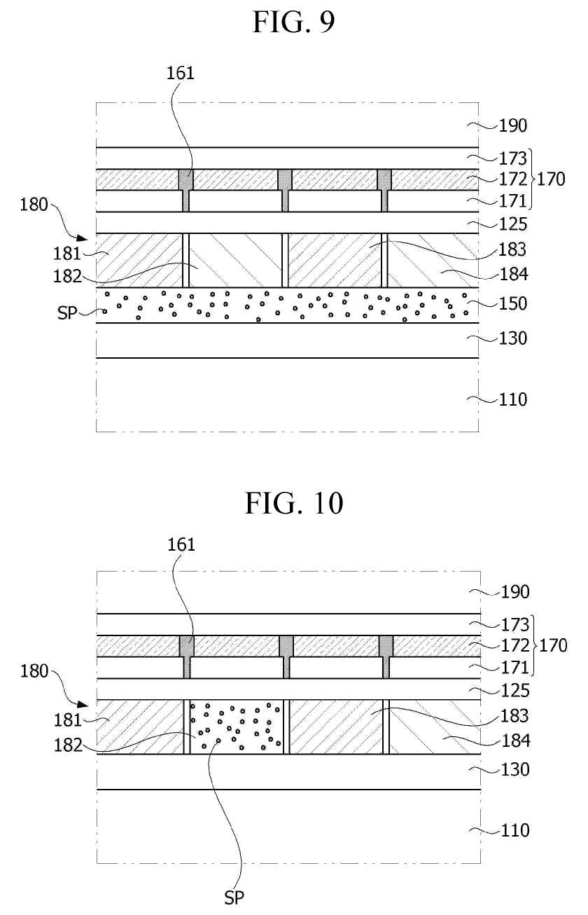

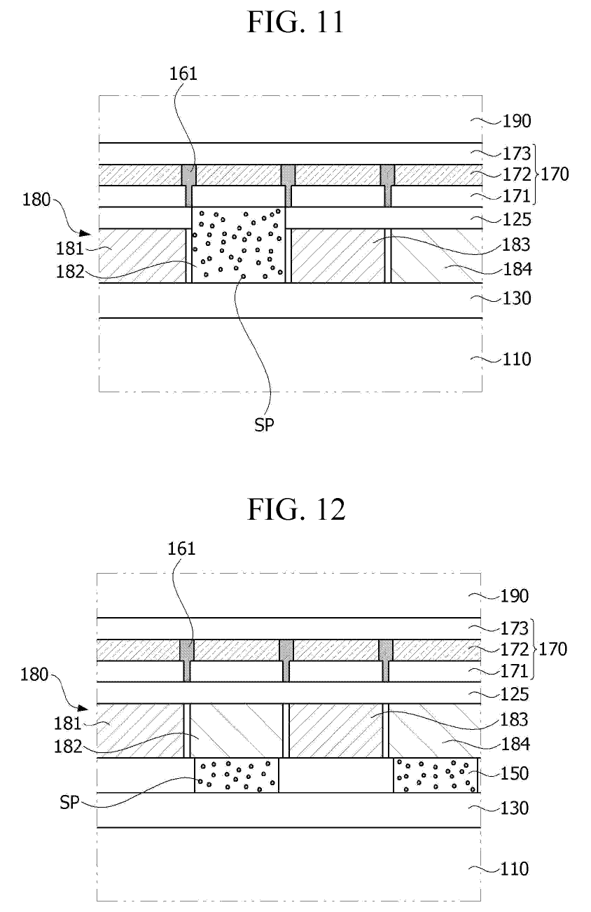

FIG. 8 is a conceptual diagram of a display device according to another embodiment of the present disclosure. FIG. 9 is a first modified example of FIG. 8. FIG. 10 is a second modified example of FIG. 8. FIG. 11 is a third modified example of FIG. 8. FIG. 12 is a fourth modified example of FIG. 8.

Referring to FIG. 8, the display device includes a substrate 110, a circuit layer 130, an emission part 170, and a color filter layer 180.

The substrate 110 can be made of an insulating material selected from the group consisting of glass, quartz, ceramic, and plastic. However, the present embodiments are not limited thereto. The substrate 110 can include a metal such as stainless steel.

A buffer layer 121 can be disposed on the substrate 110. The buffer layer 121 can include one or more films selected from various inorganic films and organic films. The buffer layer 121 can planarize a surface while preventing impurities such as moisture from penetrating into the circuit layer 130 or the emission part 170.

The circuit layer 130 can be disposed on the buffer layer 121. The circuit layer 130 can include a plurality of thin film transistors 140 and an insulating layer.

The thin film transistor 140 can include a source electrode 142 and a drain electrode 143 disposed on an active layer 141 and a gate electrode 144 disposed on a gate insulating film 122. The thin film transistor 140 can be a Low Temperature Poly Silicon (LTPS) transistor or an oxide transistor. Thin film transistors disposed in each pixel can have a structure in which an LTPS transistor and an oxide transistor are mixed. In various embodiments of the present disclosure, the source electrode 142 can include an extension 142a that extends on the interlayer insulating film 123 and to overlap with a pixel defining layer 161. Accordingly, a length of the source electrode 142 can be the same or greater than a length of the drain electrode 143.

A passivation film 124 can be disposed on an interlayer insulating film 123. The passivation film 124 can be made of an insulating material, and can protect the circuit layer 130. The passivation film 124 and the interlayer insulating film 123 can be made of the same material.

The color filter layer 180 can be disposed on the passivation film 124. The color filter layer 180 can include a first color filter 181, a second color filter 182, a third color filter 183, and a fourth color filter 184. The first color filter 181 can be a red color filter, the second color filter 182 can be a green color filter, the third color filter 183 can be a blue color filter, and the fourth color filter 184 can be a white color filter.

A planarization layer 125 can be disposed on the color filter layer 180. The planarization layer 125 can include the same material as the passivation film 124, but the present embodiments are not limited thereto.

The emission part 170 according to an embodiment of the present disclosure can be a white organic light emitting diode (WOLED) that emits white light. In addition, the emission part 170 can have a tandem structure in which two emission layers 172 are connected in series to emit white light.

The emission part 170 can include a first electrode 171, a second electrode 173 disposed on the first electrode 171, and an emission layer 172 disposed between the first electrode 171 and the second electrode 173. The emission part 170 can emit white light or blue light.

Holes and electrons are injected into the emission layer 172 from the first electrode 171 and the second electrode 173, respectively. Light emission occurs when excitons formed by recombination of the injected holes and electrons drop from an excited state to a ground state.

The first electrode 171 is a transparent electrode, and the second electrode 173 can be a reflective electrode. Accordingly, light emitted from the emission layer 172 is emitted through the first electrode 171, the color filter layer 180, and the substrate 110. For example, the display device according to an embodiment of the present disclosure can have a bottom emission type structure.

The first electrode 171 can include a Transparent Conductive Oxide (TCO). The transparent conductive oxide (TCO) can include Indium Tin Oxide (ITO), Indium Zinc Oxide (IZO), Zinc Oxide (ZnO), Aluminum Zinc Oxide (AZO), Indium Oxide (In2O3), or the like, and these can be used alone or in combination. Since the transparent conductive oxide (TCO) has a relatively high work function, hole injection is facilitated through the first electrode 171 including the transparent conductive oxide (TCO). However, the present embodiments are not limited thereto.

The second electrode 173 can include one or more metals among magnesium (Mg), silver (Ag), gold (Au), calcium (Ca), lithium (Li), chromium (Cr), copper (Cu), and aluminum (Al), or an alloy thereof. However, the present embodiments are not limited thereto.

A pixel defining layer 161 can have an opening. The opening of the pixel defining layer 161 can expose a portion of the first electrode 171. An emission layer 172 can be disposed on the exposed first electrode 171.

An encapsulation layer 163 can be disposed on the second electrode 173. The encapsulation layer 163 can protect the emission part 170. The encapsulation layer 163 can have a structure in which at least one organic layer and at least one inorganic layer are alternately disposed to prevent external air such as moisture or oxygen from penetrating into the emission part 170.

The display device implements red, green, blue, and white by the color filter layer 180 disposed in an emission direction of the emission part 170. The color filter layer 180 is disposed in an emission area. For example, each color filter layer 180 is disposed to overlap with the first electrode 171 of the emission part 170. Each color filter layer 180 is disposed below the first electrode 171, but the present embodiments are not limited thereto.

The first color filter 181 can have a red-based color, the second color filter 182 can have a green-based color, and the third color filter 183 can have a blue-based color.

The first color filter 181 has a red pigment, the second color filter 182 has a green pigment, and the third color filter 183 has a blue pigment. As the red pigment, green pigment, and blue pigment, known pigments commonly used in color filter formation can be used. The fourth color filter 184 that implements white need not have a separate color.

An optical sheet 200 can be disposed below the substrate 110. Accordingly, light generated in the emission layer 172 can be emitted to the outside through the first electrode 171, the color filter layer 180, the substrate 110, and the optical sheet 200.

Light incident on the optical sheet 200 can be reflected by various layers such as the circuit layer 130 and the color filter layer 180. As described above, reflected light can be scattered by the adhesive layer 210 and the anti-glare layer 230 of the optical sheet 200. Accordingly, the sparkling phenomenon can be suppressed.

Referring to FIG. 9, a scattering layer 150 can be disposed between the substrate 110 and the color filter layer 180. The scattering layer 150 can be formed by dispersing scattering particles SP in various insulating films between the substrate 110 and the color filter layer 180. For example, the scattering layer 150 can be a passivation film between the substrate 110 and the color filter layer 180, but the present embodiments are not limited thereto.

According to an embodiment of the present disclosure, the scattering layer 150 can be disposed entirely on the substrate 110. According to this configuration, reflected light can be more effectively scattered, thereby suppressing the sparkling phenomenon.

Referring to FIG. 10, the scattering layer 150 can be disposed in the second color filter 182 that implements green and/or the fourth color filter 184 that implements white. Among blue, green, red, and white light, the sparkling phenomenon can be relatively easily visible with green light. Accordingly, when scattering particles SP are dispersed in a green color filter, the sparkling phenomenon can be effectively suppressed by scattering the green light.

In addition, since a white color filter does not disperse a separate pigment, when scattering particles SP are dispersed in a white color filter, the sparkling phenomenon can be effectively suppressed without lowering transmittance.

According to an embodiment of the present disclosure, scattering particles SP can be dispersed only in a green color filter, or scattering particles SP can be dispersed only in a white color filter. Alternatively, scattering particles SP can be dispersed in both a green color filter and a white color filter simultaneously. In this case, the concentration of scattering particles SP dispersed in the green color filter and the white color filter can be different from each other. For example, since the green color filter needs to include a green pigment, the concentration of scattering particles SP can be relatively lower than that in the white color filter. However, the present embodiments are not limited thereto.

Referring to FIG. 11, the second color filter 182 and/or the fourth color filter 184 in which scattering particles SP are dispersed can penetrate the planarization layer 125 and contact the first electrode 171. In this case, the area of the green color filter and/or the white color filter in which scattering particles SP are dispersed increases, so that reflected light can be effectively scattered.

Referring to FIG. 12, the scattering layer 150 can be disposed to correspond to only some color filters. For example, scattering particles SP can be disposed only in areas of the scattering layer 150 corresponding to the second color filter 182 and/or the fourth color filter 184. In this case, the width of the areas where scattering particles SP are disposed can correspond to the width of the second color filter and/or the fourth color filter. However, the present embodiments are not limited thereto. For example, the width of the areas where scattering particles SP are disposed can be larger or smaller than the width of the second color filter and/or the fourth color filter. However, the present embodiments are not limited thereto.

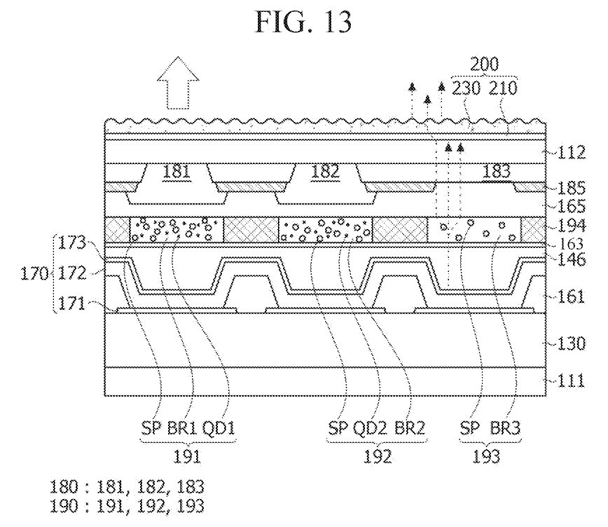

FIG. 13 is a conceptual diagram of a display device according to another embodiment of the present disclosure.

Referring to FIG. 13, the display device can include a display panel 100, a light control layer 190 disposed on the display panel 100, and a color filter layer 180 disposed on the light control layer 190.

The display panel 100 can include a first substrate 111, a circuit layer 130 disposed on the first substrate 111, and an emission part 170 disposed on the circuit layer 130.

The first substrate 111 can be a glass substrate, a metal substrate, a polymer substrate, or the like. However, the present embodiments are not limited thereto. For example, the first substrate 111 can be an inorganic layer, an organic layer, a functional layer, or a composite material layer. However, the present embodiments are not limited thereto.

The circuit layer 130 can be disposed on the first substrate 111. The circuit layer 130 can include a plurality of transistors. The transistors can each include a drain electrode, a source electrode, and a gate electrode. For example, the circuit layer 130 can include a switching transistor and a driving transistor for driving the emission part 170. However, the present embodiments are not limited thereto.

The emission part 170 can include a first electrode 171, an emission layer 172, and a second electrode 173. In an embodiment of the present disclosure, the emission part 170 can include a quantum dot light-emitting diode.

The emission layer 172 can include an organic light-emitting material or quantum dots as an emission material. The emission part 170 can be partitioned by a pixel defining layer 161. The pixel defining layer 161 can be an organic layer. An opening of the pixel defining layer 161 can expose at least a portion of the first electrode 171.

In the emission part 170 according to an embodiment of the present disclosure, the first electrode 171 has conductivity. The first electrode 171 can be formed of a metal alloy or a conductive compound. The first electrode 171 can be an anode. The first electrode 171 can be a pixel electrode.

In the emission part 170 according to an embodiment of the present disclosure, the first electrode 171 can be a reflective electrode. However, the present embodiment is not limited thereto. For example, the first electrode 171 can be a transmissive electrode or a semi-transmissive electrode. However, the present embodiments are not limited thereto.

The second electrode 173 can be a common electrode or a cathode. The second electrode 173 can be a transmissive electrode, a semi-transmissive electrode, or a reflective electrode.

An encapsulation layer 163 can be disposed on the emission part 170. For example, in an embodiment of the present disclosure, the encapsulation layer 163 is disposed on the second electrode 173, and can be disposed to fill an opening. The encapsulation layer 163 can include at least one organic film (hereinafter, an encapsulation organic film) and at least one inorganic film (hereinafter, an encapsulation inorganic film), wherein the encapsulation inorganic film and the encapsulation organic film can be alternately disposed. However, the present embodiments are not limited thereto.

The encapsulation inorganic film protects the emission part 170 from moisture/oxygen, and the encapsulation organic film protects the emission part 170 from foreign substances such as dust particles. The encapsulation inorganic film can include silicon nitride, silicon oxynitride, silicon oxide, titanium oxide, or aluminum oxide, and is not particularly limited thereto. The encapsulation organic film can include an acrylic compound, an epoxy compound, or the like. The encapsulation organic film can include a photopolymerizable organic material and is not particularly limited.

The display device according to an embodiment of the present disclosure can include a light control layer 190. The light control layer 190 can include a partition pattern 194 and light control parts 191, 192, and 193.

The light control parts 191, 192, and 193 included in the light control layer 190 can be spaced apart from each other by the partition pattern 194. Although the partition pattern 194 is illustrated as not overlapping with the light control parts 191, 192, and 193, edges of the light control parts 191, 192, and 193 can at least partially overlap with the partition pattern 194.

The light control parts 191, 192, and 193 can be configured to convert a wavelength of light provided from the emission part 170 or to transmit the provided light without wavelength conversion.

The light control layer 190 according to an embodiment of the present disclosure can include quantum dots (QD). The quantum dots (QD) can include first quantum dots (QD1) and second quantum dots (QD2). For example, the first light control part 191 includes first quantum dots (QD1) that convert emitted light into first light, the second light control part 192 includes second quantum dots (QD2) that convert emitted light into second light, and the third light control part 193 can transmit emitted light. The emitted light is light having a center wavelength of 440 nm to 460 nm, the first light is light having a center wavelength of 600 nm to 640 nm, and the second light can be light having a center wavelength of 510 nm to 540 nm. However, the present embodiments are not limited thereto.

The first light control part 191 provides first light which is red light, the second light control part 192 provides second light which is green light, and the third light control part 193 can transmit blue light among emitted light provided from the emission part 170. For example, the first quantum dots (QD1) can be red quantum dots and the second quantum dots (QD2) can be green quantum dots. However, the present embodiments are not limited thereto.

The quantum dots (QD) can include a core (CO), and a shell surrounding the core. In an embodiment of the present disclosure, the core can include a group III-V semiconductor compound. The core can be a group III-V InP compound. The core can include indium (In) and phosphorus (P). The core can be a binary compound composed of indium and phosphorus. Quantum dots (QD) according to an embodiment of the present disclosure can emit light having a desired maximum emission wavelength by including the core including a group III-V semiconductor compound. For example, the first quantum dots (QD1) can absorb blue light and emit red light, and the second quantum dots (QD2) can absorb blue light and emit green light. However, the present embodiments are not limited thereto.

The light control layer 190 can include scattering particles SP. The first light control part 191 includes first quantum dots (QD1) and scattering particles SP, the second light control part 192 includes second quantum dots (QD2) and scattering particles SP, and the third light control part 193 need not include quantum dots and can include scattering particles SP.

The scattering particles SP can be inorganic particles. For example, the scattering particles SP can include at least one of TiO2, Al2O3, SiO2, ZnO, ZrO2, BaTiO3, Ta2O5, Ti3O5, ITO, IZO, ATO, ZnO-Al, Nb2O3, SnO, and MgO. However, the present embodiments are not limited thereto.

Each of the first light control part 191, the second light control part 192, and the third light control part 193 can include base resins BR1, BR2, and BR3, respectively, in which the quantum dots QD1 and QD2 and/or scattering particles SP are dispersed.

The light control layer 190 can include a barrier layer 164. The barrier layer 164 can serve to prevent penetration of moisture and/or oxygen (hereinafter referred to as 'moisture/oxygen'). The barrier layer 164 can be disposed on the light control parts 191, 192, and 193 to block the light control parts 191, 192, and 193 from being exposed to moisture/oxygen. Meanwhile, the barrier layer 164 can cover the light control parts 191, 192, and 193. In addition, a barrier layer 165 can also be provided between the light control parts 191, 192, and 193 and the color filters 181, 182, and 183.

The barrier layers 164 and 165 can include at least one inorganic layer. For example, the barrier layers 164 and 165 can be made of an inorganic material. For example, the barrier layers 164 and 165 can be made of silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a metal thin film with secured light transmittance. Meanwhile, the barrier layers 164 and 165 can further include an organic film. The barrier layers 164 and 165 can be composed of a single layer or a plurality of layers. However, the present embodiments are not limited thereto.

In a display device according to an embodiment of the present disclosure, the color filter layer 180 can be disposed on the light control layer 190. For example, the color filter layer 180 can be directly disposed on the light control layer 190. In this case, the barrier layer 165 can be omitted. However, the present embodiments are not limited thereto.

The color filter layer 180 can include a light-shielding part 185 and color filters 181, 182, and 183. The color filter layer 180 can include a first color filter 181 that transmits first light, a second color filter 182 that transmits second light, and a third color filter 183 that transmits third light. For example, the first color filter 181 can be a red color filter, the second color filter 182 can be a green color filter, and the third color filter 183 can be a blue color filter. However, the present embodiments are not limited thereto.

Each of the color filters 181, 182, 183 can include a polymer photosensitive resin and a pigment or dye. The first color filter 181 includes a red pigment or dye, the second color filter 182 includes a green pigment or dye, and the third color filter 183 can include a blue pigment or dye. The third color filter 183 need not include a pigment or dye. The third color filter 183 can include a polymer photosensitive resin and need not include a pigment or dye. The third color filter 183 can be transparent. The third color filter 183 can be formed of a transparent photosensitive resin.

The light-shielding part 185 can be a black matrix. The light-shielding part 185 can be formed of an organic light-shielding material or an inorganic light-shielding material including a black pigment or a black dye. The light-shielding part 185 can prevent a light leakage phenomenon and distinguish boundaries between adjacent color filters 181, 182, and 183. In addition, in an embodiment of the present disclosure, the light-shielding part 185 can be formed as a blue filter.

The display device according to an embodiment of the present disclosure can further include a second substrate 112 disposed on the color filter layer 180. The second substrate 112 can be a member that provides a base surface on which the color filter layer 180 and the light control layer 190 are disposed. The second substrate 112 can be a glass substrate, a metal substrate, a plastic substrate, or the like.

An optical sheet 200 can be disposed on an upper portion of the second substrate 112. Light generated in the emission layer 172 can be emitted to the outside through the first electrode 171, the color filter layer 180, the second substrate 112, and the optical sheet 200.

Light incident on the optical sheet 200 can be reflected by various layers such as the color filter layer 180 and the light control part 190. As described above, reflected light can be scattered by scattering particles SP dispersed in the light control part 190. In addition, reflected light can be scattered multiple times by an adhesive layer 210 and an anti-glare layer 230 of the optical sheet 200. Accordingly, the sparkling phenomenon can be suppressed.

The problems, means for solving the problems, and effects described in the present disclosure above do not specify essential features of the claims, and thus the scope of the claims is not limited by the matters described in the content of the present disclosure.

Although embodiments of the present disclosure have been described in more detail above with reference to the accompanying drawings, the present disclosure is not necessarily limited to these embodiments, and various modifications can be made within the scope without departing from the technical spirit of the present disclosure. Accordingly, the embodiments disclosed in the present disclosure are not intended to limit the technical spirit of the present disclosure but to explain it, and the scope of the technical spirit of the present disclosure is not limited by these embodiments. Therefore, it should be understood that the embodiments described above are illustrative in all respects and not restrictive. The scope of protection of the present disclosure should be construed by the claims, and all technical spirits within the equivalent scope should be construed as being included in the scope of the present disclosure.

### DESCRIPTION OF REFERENCE NUMBERS

100: Display panel

200: Optical sheet

210: Adhesive layer

220: light-transmissive support

230: Anti-glare layer

240: Low refractive index layer

What is claimed is:

1. A display device comprising:
a display panel; and
an optical sheet disposed on the display panel,
wherein the optical sheet comprises:
an adhesive layer disposed on the display panel;
a base layer disposed on the adhesive layer; and
an anti-glare layer disposed on the base layer, and
wherein the anti-glare layer has a plurality of concave-convex portions, the adhesive layer includes scattering particles, and a haze of the anti-glare layer is lower than a total haze of the optical sheet.

2. The display device according to claim 1, wherein:
the anti-glare layer includes first particles, second particles, and a resin in which the first particles and the second particles are dispersed, and
an average diameter of the first particles is smaller than an average diameter of the second particles.

3. The display device according to claim 1, further comprising:
a polarizing layer disposed between the base layer and the anti-glare layer.

4. The display device according to claim 1, further comprising:
a first polarizing layer disposed between the base layer and the anti-glare layer,
a second polarizing layer disposed between the first polarizing layer and the base layer, and
an optical layer disposed between the first polarizing layer and the second polarizing layer,
wherein the optical layer includes the scattering particles.

5. The display device according to claim 1, wherein a haze of the adhesive layer is higher than the haze of the anti-glare layer.

6. The display device according to claim 1, wherein a haze of the adhesive layer is lower than the haze of the anti-glare layer.

7. The display device according to claim 1, wherein an external haze of the anti-glare layer is higher than an internal haze of the anti-glare layer.

8. The display device according to claim 1, wherein an external haze of the anti-glare layer is lower than an internal haze of the anti-glare layer.

9. The display device according to claim 1, further comprising:
a low refractive index layer disposed on the anti-glare layer,
wherein the low refractive index layer is formed to be curved along the plurality of concave-convex portions.

10. The display device according to claim 9, wherein the low refractive index layer includes low refractive index particles.

11. The display device according to claim 9, wherein the low refractive index layer includes the scattering particles.

12. The display device according to claim 1, wherein light reflected concave-convex portions PT1 from the display panel undergoes a primary scattering by the scattering particles and a secondary scattering by the anti-glare layer.

13. The display device according to claim 1, wherein the scattering particles in the adhesive layer have an average particle diameter of approximately 0.1 μm to approximately 4.0 μm.

14. The display device according to claim 1, wherein the anti-glare layer has the haze of approximately 15% to approximately 70%.

15. The display device according to claim 2, wherein the first particles of the anti-glare layer and the scattering particles of the adhesive layer comprise a same material.

16. The display device according to claim 1, wherein the display panel comprises:
a substrate;
a circuit layer disposed on the substrate;
a color filter layer disposed on the circuit layer;
an insulating layer disposed on the color filter layer;
a plurality of first electrodes disposed on the insulating layer;
a pixel defining layer disposed between the plurality of first electrodes;
an emission layer disposed on the plurality of first electrodes; and
a second electrode disposed on the emission layer,
wherein the color filter layer includes a first color filter, a second color filter, a third color filter, and a fourth color filter having different colors from each other.

17. The display device according to claim 16, further comprising:
a scattering layer disposed between the color filter layer and the substrate.

18. The display device according to claim 17, wherein the scattering layer is a passivation film disposed entirely on the substrate.

19. The display device according to claim 16, wherein:
the second color filter or the fourth color filter includes the scattering particles,
the second color filter is a green color filter, and
the fourth color filter is a white color filter.

20. A display device comprising:
a display panel configured to display images; and
an optical sheet on the display panel,
wherein the display panel comprises:
a substrate;
a scattering layer disposed on the substrate; and
a color filter layer disposed on the scattering layer, and
wherein the optical sheet comprises an adhesive layer including scattering particles and an anti-glare layer having concave-convex portions.
